(19) United States
(12) Patent Application Publication
(10) Pub. No.: US 2007/0063647 A1
(43) Pub. Date: Mar. 22, 2007

(54) Light emitting diode for emitting white light

(75) Inventor: Tai-Cherng Yu, Tu-Cheng (TW)

Correspondence Address: PCE INDUSTRY, INC.;ATT. CHENG-JU CHIANG JEFFREY T. KNAPP, 458 E. LAMBERT ROAD, FULLERTON, CA, 92835, US

(73) Assignee: HON HAI Precision Industry CO., LTD., Tu-Cheng City (TW)

(21) Appl. No.: 11/377,791

(22) Filed: Mar. 16, 2006

(30) Foreign Application Priority Data
Sep. 16, 2005 (CN) 200510037338.5

(51) Int. Cl. H05B 33/04; H01L 51/50

(52) U.S. Cl. 313/512; 257/98

(57) ABSTRACT

A light emitting diode (10) includes a red light emitting diode chip (12), a green light emitting diode chip (14), a blue light emitting diode chip (16), and a lens (18). The red light emitting diode chip emits red light. The green light emitting diode chip emits green light. The blue light emitting diode chip emits blue light. The lens encapsulates the red light emitting diode chip, the green light emitting diode chip and the blue light emitting diode chip such that the red light, the green light and the blue light are merged in the lens. The merged light passes through the lens and appears white to a human observer. The LED is capable of providing white light with a good performance in high brightness.

### BACKGROUND OF THE INVENTION

1. Field of the Invention

The present invention relates to light emitting diodes (LEDs) for emitting white light, and particularly to an LED comprising different LED chips.

2. Discussion of the Related Art

A conventional LED for emitting white light generally includes a blue LED chip, and phosphor powders coated on the blue LED chip. The blue LED chip emits blue light, and the blue light excites the phosphor powders so that red light and green light are also emitted. The blue light, the red light, and the green light are merged together at a predetermined position. The merged light appears white to a human observer.

The merged light collectively has a color temperature of about 5600° K (Kelvin) at most. Color temperature is defined as the color produced by a symbolic black body radiator when heated to a particular temperature, measured in degrees Kelvin. Color temperature is an important parameter in photography used to characterize the quality of a light source such as an LED. Light sources rich in red light have a low color temperature, and light sources rich in blue light have a high color temperature. A high color temperature provides white light having a high brightness. An upper limit of the color temperature of the white light depends on the kinds of phosphor powders employed. Because the color temperature of the white light emitted from the conventional LED is generally limited to below 5600° K, the conventional LED cannot provide satisfactory brightness for certain applications.

A high brightness of the white light may be achieved using particular kinds of phosphor powders. Nevertheless, the phosphor powders themselves constitute a limitation on the level of brightness attainable. The very need for phosphor powders prevents the LED from emitting white light having a good performance in high brightness.

What is needed, therefore, is an LED for emitting white light with a good performance in high brightness.

### SUMMARY OF THE INVENTION

A preferred embodiment provides an LED including a red LED chip, a green LED chip, a blue LED chip, and a lens. The red LED chip emits red light. The green LED chip emits green light. The blue LED chip emits blue light. The lens encapsulates the red LED chip, the green LED chip, and the blue LED chip such that the red light, the green light and the blue light are merged in the lens. The merged light passes through the lens and appears white to a human observer. The LED is capable of providing white light with a good performance in high brightness.

Other advantages and novel features will become more apparent from the following detailed description of present LED, when taken in conjunction with the accompanying drawings.

### BRIEF DESCRIPTION OF THE DRAWINGS

Many aspects of the present LED can be better understood with reference to the following drawings. The components in the drawings are not necessarily to scale, the emphasis instead being placed upon clearly illustrating the principles of the present LED. Moreover, in the drawings, like reference numerals designate corresponding parts throughout the several views.

FIG. 1 is a schematic, cross-sectional view of an LED according to an exemplary embodiment; and

FIG. 2 is a schematic, top view of three LED chips of the LED of FIG. 1, showing approximate relative sizes and a positional relations of the three LED chips.

### DETAILED DESCRIPTION OF PREFERRED EMBODIMENTS

Reference will now be made to the drawings to describe preferred embodiment of the present LED, in detail.

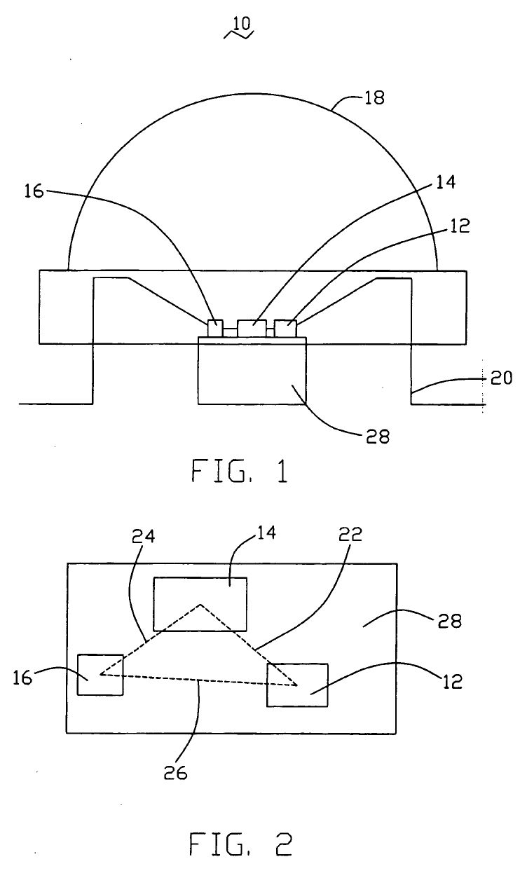

Referring to FIG. 1, an LED 10 for emitting white light according to an exemplary embodiment includes a red LED chip 12, a green LED chip 14, a blue LED chip 16, a lens 18, and a heat sink 28.

The red LED chip 12 has a first size and emits red light. The green LED chip 14 has a second size and emits green light. The blue LED chip 16 has a third size and emits blue light. The first size, the second size, and the third size are preferably all different from each other. The red LED chip 12, the green LED chip 14, and the blue LED chip 16 are arranged on the heat sink 28. The lens 18 has a predetermined thickness and a predetermined shape, and encapsulates the red LED chip 12, the green LED chip 14, and the blue LED chip 16 therein. The red light, the green light, and the blue light emitted from the red, green, and blue LED chips 12, 14, 16 are merged together in the lens 18, and pass through the lens 18 along a predetermined direction. The predetermined direction may be obtained by configuring the shape of the lens 18 accordingly. The merged light appears white to a human observer.

The merged light initially has a first amount of energy. When the merged light passes through the lens 18, the lens 18 absorbs a portion of the first amount of energy. That is, when the merged light passes through the lens 18, the first amount of energy is decreased to a second amount of energy. The thickness of the lens 18 determines in whole or in part the second amount of energy. The second amount of energy determines a brightness of the merged light as viewed by a human observer.

The color temperature of the merged light may be configured by correspondingly configuring any one or more of the first size of the red LED chip 12, the second size of the green LED chip 14, and the third size of the blue LED chip 16 accordingly. For example, when the third size of the blue LED chip 16 is increased, the color temperature of the merged light is correspondingly increased. Such color temperature increases generally cannot be achieved using conventional phosphor powders. Consequently, the LED 10 is capable of providing a high brightness with a good performance without using phosphor powders. In order to ensure that the LED 10 can be operated at an increased color temperature, the heat sink 28 is employed for dissipating heat from the LED 10. A material of the heat sink 28 generally can be an engineering plastic with a high coefficient of thermal conductivity.

Preferably, the red LED chip 12, the green LED chip 14, and the blue LED chip 16 are electrically connected in series. By doing so, the red LED chip 12, the green LED chip 14, and the blue LED chip 16 can be simultaneously biased between a pair of common electrodes 20.

Referring also to FIG. 2, the red LED chip 12 and the green LED chip 14 are separated by a first distance 22. The green LED chip 14 and the blue LED chip 16 are separated by a second distance 24. The blue LED chip 16 and the red LED chip 12 are separated by a third distance 26. In the illustrated embodiment, the first distance 22, second distance 24, and third distance 26 are defined according to centers of the red, green, and blue LED chips 12, 14, 16. By appropriately configuring the first distance 22, the second distance 24, the third distance 26, or any combination thereof, a desired position where the red, green, and blue light are merged and hence appear white can be obtained. The first distance 22, the second distance 24, and the third distance 26 typically are all different from each other.

The LED 10 has at least the following advantages. First, the LED 10 can provide white light with a good performance in high brightness by, for example, increasing the third size of the blue LED chip 16. This is attained without the need for using phosphor powders. Second, a desired position in the LED 10 where the red, green, and blue light are merged and hence appear white may be obtained by configuring the first distance, the second distance, the third distance, or any combination thereof accordingly Third, the shape of the lens 18 may be configured in order to control the emitting direction of the merged light. Fourth, the thickness of the lens 18 may be configured in order to obtain a desired amount of energy of the merged light.

It is to be understood that the above-described embodiment is intended to illustrate rather than limit the invention. Variations may be made to the embodiment without departing from the spirit of the invention as claimed. The above-described embodiments are intended to illustrate the scope of the invention and not restrict the scope of the invention.

What is claimed is:

1. A light emitting diode for emitting white light, comprising:
a red light emitting diode chip for emitting red light;
a green light emitting diode chip for emitting green light;
a blue light emitting diode chip for emitting blue light; and
a lens encapsulating the red light emitting diode chip, the green light emitting diode chip, and the blue light emitting diode chip such that the red light, the green light, and the blue light are merged in the lens, the merged light passing through the lens and appearing white to a human observer.

2. The light emitting diode as claimed in claim 1, wherein the red light emitting diode chip, the green light emitting diode chip, and the blue light emitting diode chip are electrically connected in series.

3. The light emitting diode as claimed in claim 1, wherein the red light emitting diode chip, the green light emitting diode chip, and the blue light emitting diode chip respectively have a first size, a second size, and a third size, and the first size, the second size, and the third size are all different from each other.

4. The light emitting diode as claimed in claim 3, wherein the third size is larger than the second size and larger than the first size.

5. The light emitting diode as claimed in claim 1, wherein the red light emitting diode chip and the green light emitting diode chip are separated by a first distance, the blue light emitting diode chip and the green light emitting diode chip are separated by a second distance, the red light emitting diode chip and the blue light emitting diode chip are separated by a third distance, and the first distance, the second distance, and the third distance are all different from each other.

6. The light emitting diode as claimed in claim 1, wherein the red light emitting diode chip, the green light emitting diode chip, and the blue light emitting diode chip are arranged on a heat sink.

7. The light emitting diode as claimed in claim 6, wherein a material of the heat sink is an engineering plastic with a high coefficient of thermal conductivity.

8. A light emitting diode for emitting white light, comprising:
a red light emitting diode chip for emitting red light;
a green light emitting diode chip for emitting green light; and
a blue light emitting diode chip for emitting blue light;
wherein the red light emitting diode chip, the green light emitting diode chip, and the blue light emitting diode chip are electrically connected in series, and are arranged such that the red light, the green light, and the blue light are merged, the merged light appearing white to a human observer.

9. The light emitting diode as claimed in claim 8, wherein the red light emitting diode chip, the green light emitting diode chip, and the blue light emitting diode chip respectively have a first size, a second size, and a third size, and the first size, the second size, and the third size are all different from each other.

10. The light emitting diode as claimed in claim 9, wherein the third size is larger than the second size and larger than the first size.

11. The light emitting diode as claimed in claim 8, wherein the red light emitting diode chip and the green light emitting diode chip are separated by a first distance, the blue light emitting diode chip and the green light emitting diode chip are separated by a second distance, the red light emitting diode chip and the blue light emitting diode chip are separated by a third distance, and the first distance, the second distance, and the third distance are all different from each other.

12. The light emitting diode as claimed in claim 8, wherein the red light emitting diode chip, the green light emitting diode chip and the blue light emitting diode chip are arranged on a heat sink.

13. The light emitting diode as claimed in claim 12, wherein a material of the heat sink is an engineering plastic with a high coefficient of thermal conductivity.
